(19) United States
(12) Patent Application Publication
(10) Pub. No.: US 2025/0060321 A1
(43) Pub. Date: Feb. 20, 2025

(54) OPTICAL INSPECTION OF WAFERS IN MANUFACTURING SYSTEMS

(71) Applicant: Applied Materials, Inc., Santa Clara, CA (US)

(72) Inventors: Elias Anthony Martinez, San Jose, CA (US); Sidharth Bhatia, Santa Cruz, CA (US); Sarah Michelle Bobek, Santa Clara, CA (US); Ka Shun Wong, San Jose, CA (US); Zhi Wang, Redwood City, CA (US); Martin J. Seamons, San Jose, CA (US); Raj Singu, San Jose, CA (US); Abdul Aziz Khaja, San Jose, CA (US); Ganesh Balasubramanian, Fremont, CA (US); Mark McTaggart Wylie, Meridian, ID (US)

(21) Appl. No.: 18/234,777

(22) Filed: Aug. 16, 2023

(51) Int. Cl. G01N 21/95; G01N 35/00

(52) U.S. Cl. CPC G01N 21/9505; G01N 35/0099

(57) ABSTRACT

Disclosed are systems and techniques for fast and efficient detection of defects in wafers, including a system that has a factory interface (FI) coupled to a wafer carrier and a load lock chamber. The FI includes a robot fetches a wafer from the wafer carrier and deliver the first wafer to an aligner device. The aligner device imparts rotational motion to the wafer and identifies, using the rotational motion of the wafer, a position of a reference feature of the wafer. The FI further includes an optical inspection system that collects, during the rotational motion imparted to the wafer, an imaging data for the first wafer. The system further includes a processing device that performs evaluation, using the imaging data, of a presence of defect(s) in the wafer, and evaluates suitability of the wafer for wafer processing.

### TECHNICAL FIELD

This instant specification generally relates to ensuring quality control of materials manufactured in substrate processing systems. More specifically, the instant specification relates to systems and techniques of efficient optical inspections of manufacturing products during various stages of the manufacturing process, including initial, intermediate, and/or final manufacturing products.

### BACKGROUND

Manufacturing of modern materials often involves various deposition techniques, such as chemical vapor deposition (CVD) or physical vapor deposition (PVD), in which atoms of one or more selected types are deposited on a substrate (wafer) held in low or high vacuum environments that are provided by vacuum deposition chambers. Manufacturing further includes various other techniques, such as etching, patterning, polishing, cleaning, stress mitigation, and/or the like. Materials manufactured in this manner include monocrystals, semiconductor films, fine coatings, and numerous other substances used in practical applications, e.g., electronic device manufacturing. Many of these applications rely on the quality of the materials grown in substrate processing systems, which in turn depends on the quality of wafers (e.g., bare wafers or wafers that underwent various preprocessing operations) used as substrates for device manufacturing. A wafer/substrate carrier may be docked to a load port of an equipment front end module (factory interface), where one or more substrates may be transferred to a load lock chamber or a process chamber (e.g., by a transfer robot). An environmentally-controlled atmosphere may be provided within and between the substrate carrier and the process chambers. To maintain isolation of inter-chamber environments and to increase product throughput, various robotic techniques of wafer manipulation and wafer inspection techniques.

### SUMMARY

In one implementation, disclosed is a manufacturing system that includes an aligner device to impart a rotational motion to a wafer and identify, using the rotational motion of the wafer, a position of a reference feature of the wafer. The manufacturing system further includes an optical inspection system to collect, during the rotational motion imparted by the aligner device to the wafer, an imaging data for at least a portion of the wafer. The manufacturing system further includes a processing device to identify, using the collected imaging data, presence of one or more defects in the wafer.

In another implementation, disclosed is a system that includes a factory interface (FI) coupled to a wafer carrier and a load lock chamber. The FI includes a robot to fetch a first wafer from the wafer carrier and deliver the first wafer to an aligner device. The system further includes the aligner device to impart a rotational motion to the first wafer and identify, using the rotational motion of the first wafer, a position of a reference feature of the first wafer. The system further includes an optical inspection system to collect, during the rotational motion imparted by the aligner device to the first wafer, a first imaging data for at least a portion of the first wafer. The system further includes a processing device to perform a first evaluation, using the first imaging data, of a presence of one or more defects in the first wafer. The processing device is further to determine, using the first evaluation, that the first wafer is suitable for wafer processing and cause the robot to transfer the first wafer to the load lock chamber to.

In another implementation, disclosed is a method that includes imparting, using an aligner device, a rotational motion to a wafer. The method further includes identifying, using the rotational motion of the wafer, a position of a reference feature of the wafer. The method further includes collecting, using an optical inspection system, an imaging data for at least a portion of the wafer. The imaging data is collected during the rotational motion imparted to the wafer. The method further includes identifying, using the collected imaging data, presence of one or more defects in the wafer.

### BRIEF DESCRIPTION OF THE DRAWINGS

Aspects and implementations of the present disclosure will be understood more fully from the detailed description given below and from the accompanying drawings of various aspects and implementations of the disclosure, which, however, should not be taken to limit the disclosure to the specific aspects or implementations, but are for explanation and understanding only. The drawings, described below, are for illustrative purposes and are not necessarily drawn to scale.

FIG. 1 illustrates a schematic view of a processing system (e.g., a substrate processing system), in accordance with some implementations of the present disclosure.

FIG. 2A illustrates a portion of an example optical inspection system for detection of defects in wafers rotated by an aligner, in accordance with some implementations of the present disclosure.

FIG. 2B illustrates another example optical inspection system for scanning an entire surface of wafers rotated by an aligner, in accordance with some implementations of the present disclosure.

FIG. 2C illustrates a configuration of the optical inspection system of FIG. 2B that is used for bevel edge scanning, in accordance with some implementations of the present disclosure. FIG. 2D is an illustration of various regions of a wafer edge that can be scanned using the configuration of FIG. 2C, in accordance with some implementations of the present disclosure.

FIG. 3 illustrates an example architecture of a defect detection system, operating in accordance with some implementations of the present disclosure.

FIGS. 4A-B illustrate example edge defects that can be detected by a defect detection system illustrated in conjunction with FIG. 2 and FIG. 3, in accordance with some implementations of the present disclosure.

FIG. 5 is a flow diagram of an example method of defect detection in wafers rotated by an aligner device, in accordance with some implementations of the present disclosure.

FIG. 6 depicts a block diagram of an example processing device operating in accordance with some implementations of the present disclosure.

### DETAILED DESCRIPTION

Wafers (substrates) that are delivered for processing in manufacturing chambers can include bare wafers (e.g., silicon wafers, quartz wafers, Gallium Arsenide wafers, corundum wafers), wafers that have been preprocessed (e.g., covered with one or more films, such as carbon films), or wafers that have already undergone one or more processing operations (e.g., deposition, patterning, etching, and so on). Operations with wafers (including bare wafer manufacturing) and transportation of wafers can leave or cause various defects in wafers, including but not limited to chipping near wafer edges, pitting (hole and depression formation), staining (e.g., water condensation or presence of extraneous materials), film peeling, non-uniformities of film beveling, and/or various other wafer imperfections. Undiscovered defects can result in expensive wasteful processing, sub-optimal and unusable manufacturing products, and even damage processing tools. To avoid this, wafers can be inspected using optical inspection systems and computer software that deploys various defect detection algorithms, such as image processing-based heuristic algorithms, machine learning techniques (decision-tree based algorithms), including deep learning neural networks (including but not limited to convolutional neural networks, fully-connected neural networks, and/or the like). Such inspections, however, introduce an additional step into the manufacturing process, increase the total processing time, and adversely affect the manufacturing throughput.

Aspects and implementations of the present disclosure address these and other challenges of the wafer processing technology by enabling systems and techniques for fast defect identification. In some implementations, optical inspection of wafers can be performed while a wafer undergoes an alignment process. More specifically, wafers are typically delivered to manufacturing systems in wafer (substrate) carriers, such as front opening unified pods (FOUPs), which can hold multiple wafers at different stages of processing. A FOUP may be docked at the factory interface (front-end module), and a robot (e.g., located in a load lock chamber) may retrieve wafers from the FOUP through a sealable FOUP door for processing in one of the process chambers. Similarly, the robot can return fully or partially processed wafers into the FOUP. Orientations of wafers inside the FOUP are typically not controlled to a sufficient degree that would enable the robot to pick up an automatically aligned wafer in a way that would enable immediate wafer processing. Orientation of crystallographic axes (and/or directionality of various features that can be patterned on the wafer) of a wafer fetched from a FOUP can thus be arbitrary.

Correspondingly, an additional aligner station (device) is normally deployed to align wafers relative to some reference direction, e.g., a specific direction associated with a robot blade of the robot. The aligner can spin the wafer and locate, e.g., using various techniques of machine vision, a reference feature on the wafer that communicates to the robot (and/or other wafer manufacturing tools) orientation of the wafer. Such reference features include a notch that is cut into an edge of the wafer, a flat (cut-out) portion of the wafer's edge, or any other reference feature that breaks the circular symmetry of the wafer and is detectable by mechanical or optical techniques. The aligner device typically locates these reference features over several seconds of wafer's spinning on the aligner. A moving portion of the aligner (e.g., a chuck) typically rotates with frequency of about 50-200 rpm.

As disclosed in more detail herein, optical inspection of a wafer can be performed while the wafer is rotated by the aligner. The defect inspection can be performed for the entire area of the wafer (e.g., via a line scan) or for an edge region of the wafer (e.g., within 10-15 mm from a wafer's edge). Edge regions often have a higher concentration of defects compared with the rest of the wafer's area and often determine whether the wafer is suitable for product processing. During optical inspection, a set of images of the wafer's edge (or the full area of the wafer) can be obtained by an optical inspection system and processed in real time by one or more trained defect detection models. Depending on the state of the wafer and the amount and types of identified defects, one or more decisions can be made, e.g., to use the wafer for further processing, to discard the wafer, to direct the wafer for remedial processing (e.g., removal of a deposited film and a deposition of a replacement film), and/or the like. As a result, sub-optimal wafers are prevented from entering downstream processing at no additional time cost. The advantages of the disclosed implementations include, but are not limited to, efficient and low-cost optical real-time inspections that utilize existing hardware (e.g., aligner devices), increased quality of the processing yield, and prevention of damage of various processing tools by wafers that do not conform to processing specifications.

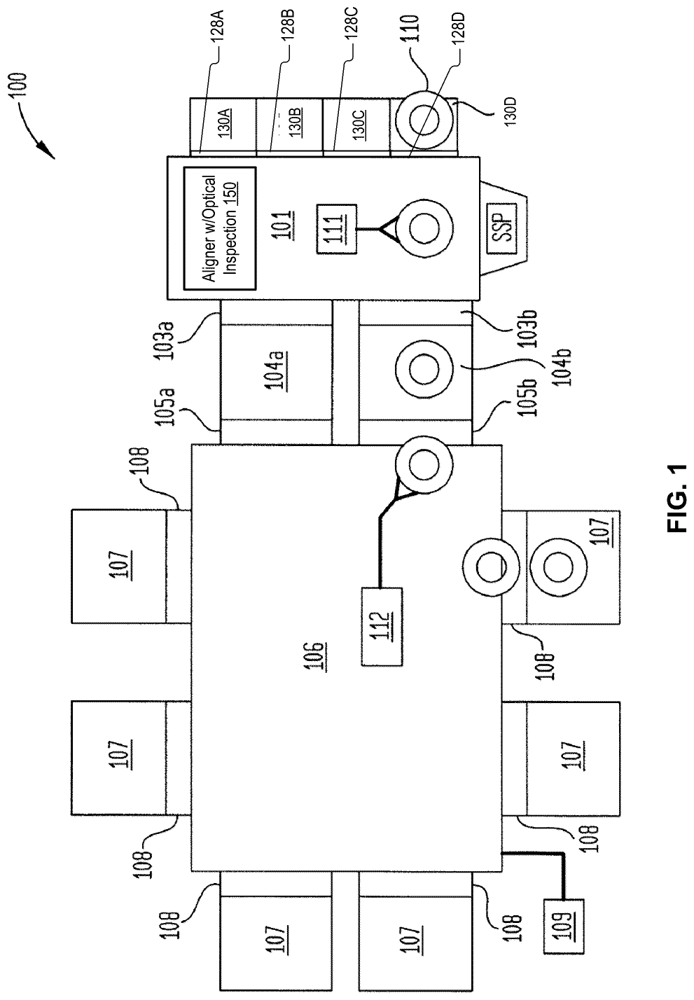

FIG. 1 illustrates a schematic view of an example processing system 100 (e.g., a wafer processing system), in accordance with some implementations of the present disclosure. The processing system 100 includes a factory interface (FI) 101 and load ports 128 (e.g., load ports 128A-D). In some implementations, the load ports 128A-D are directly mounted to (e.g., sealed against) FI 101. Enclosure systems 130 (e.g., cassette, FOUP, process kit enclosure system, or the like) are configured to removably couple (e.g., dock) to the load ports 128A-D. Referring to FIG. 1, enclosure system 130A is coupled to load port 128A, enclosure system 130B is coupled to load port 128B, enclosure system 130C is coupled to load port 128C, and enclosure system 130D is coupled to load port 128D. In some implementations, one or more enclosure systems 130 are coupled to the load ports 128 for transferring substrates and/or other items into and out of the processing system 100. Each of the enclosure systems 130 may seal against a respective load port 128. In some implementations, a first enclosure system 130A is docked to a load port 128A. Once such operation or operations are performed, the first enclosure system 130A is undocked from the load port 128A, and then a second enclosure system 130 (e.g., a FOUP containing substrate) is docked to the same load port 128A. In some implementations, an enclosure system 130 (e.g., enclosure system 130A) is a system for performing a calibration operation or a diagnostic operation. In some implementations, an enclosure system 130 (e.g., enclosure system 130B) is a process kit enclosure system for transferring content 110 such as process kit rings into and out of the processing system 100.

In some implementations, a load port 128 includes a front interface that forms an opening. The load port 128 additionally includes a horizontal surface for supporting an enclosure system 130. Each enclosure system 130 has a front interface that forms a vertical opening. The front interface of the enclosure system 130 is sized to interface with (e.g., seal to) the front interface of the load port 128 (e.g., the vertical opening of the enclosure system 130 is approximately the same size as the vertical opening of the load port 128). The enclosure system 130 is placed on the horizontal surface of the load port 128 and the vertical opening of the enclosure system 130 aligns with the vertical opening of the load port 128. The front interface of the enclosure system 130 interconnects with (e.g., clamp to, be secured to, be sealed to) the front interface of the load port 128. A bottom plate (e.g., base plate) of the enclosure system 130 has features (e.g., load features, such as recesses or receptacles, that engage with load port kinematic pin features, a load port feature for pin clearance, and/or an enclosure system docking tray latch clamping feature) that engage with the horizontal surface of the load port 128. The same load ports 128 that are used for different types of enclosure systems 130.

In some implementations, the enclosure system 130B (e.g., process kit enclosure system) includes one or more items of content 110 (e.g., one or more of a process kit ring, an empty process kit ring carrier, a process kit ring disposed on a process kit ring carrier, a placement validation wafer, etc.). In some examples, the enclosure system 130B is coupled to FI 101 (e.g., via load port 128) to enable automated transfer of a process kit ring on a process kit ring carrier into the processing system 100 for replacement of a used process kit ring.

In some implementations, the processing system 100 also includes first vacuum ports 103a, 103b coupling FI 101 to respective degassing chambers 104a, 104b. Second vacuum ports 105a, 105b are coupled to respective degassing chambers 104a, 104b and disposed between the degassing chambers 104a, 104b and a transfer chamber 106 to facilitate transfer of substrates and other content 110 (e.g., process kit rings) into the transfer chamber 106. In some implementations, a processing system 100 includes and/or uses one or more degassing chambers 104 and a corresponding number of vacuum ports 103, 105 (e.g., a processing system 100 includes a single degassing chamber 104, a single first vacuum port 103, and a single second vacuum port 105). The transfer chamber 106 includes a plurality of processing chambers 107 (e.g., four processing chambers 107, six processing chambers 107, etc.) disposed therearound and coupled thereto. The processing chambers 107 are coupled to the transfer chamber 106 through respective ports 108, such as slit valves or the like. In some implementations, FI 101 is at a higher pressure (e.g., atmospheric pressure) and the transfer chamber 106 is at a lower pressure (e.g., vacuum). Each degassing chamber 104 (e.g., load lock, pressure chamber) has a first door (e.g., first vacuum port 103) to seal the degassing chamber 104 from FI 101 and a second door (e.g., second vacuum port 105) to seal the degassing chamber 104 from the transfer chamber 106. Content is to be transferred from FI 101 into a degassing chamber 104 while the first door is open and the second door is closed, the first door is to close, the pressure in the degassing chamber 104 is to be reduced to match the transfer chamber 106, the second door is to open, and the content is to be transferred out of the degassing chamber 104. A local center finding (LCF) device is to be used to align the content in the transfer chamber 106 (e.g., before entering a processing chamber 107, after leaving the processing chamber 107).

In some implementations, the processing chambers 107 includes or more of etch chambers, deposition chambers (including atomic layer deposition, chemical vapor deposition, physical vapor deposition, or plasma enhanced versions thereof), anneal chambers, or the like.

Factory interface 101 includes a factory interface robot 111. Factory interface robot 111 includes a robot arm, such as a selective compliance assembly robot arm (SCARA) robot. Examples of a SCARA robot include a 2 link SCARA robot, a 3 link SCARA robot, a 4 link SCARA robot, and so on. The factory interface robot 111 includes an end effector on an end of the robot arm. The end effector is configured to pick up and handle specific objects, such as wafers. Alternatively, or additionally, the end effector is configured to handle objects such as a calibration substrate and process kit rings (edge rings). The robot arm has one or more links or members (e.g., wrist member, upper arm member, forearm member, etc.) that are configured to be moved to move the end effector in different orientations and to different locations.

The factory interface robot 111 is configured to transfer objects between enclosure systems 130 (e.g., cassettes, FOUPs) and degassing chambers 104a, 104b (or load ports). The factory interface robot 111 is taught a fixed location relative to a load port 128 using the enclosure system 130 in implementations. The fixed location in one implementation corresponds to a center location of an enclosure system 130A placed at a particular load port 128, which in implementations also corresponds to a center location of an enclosure system 130B placed at the particular load port 128. Alternatively, the fixed location may correspond to other fixed locations within the enclosure system 130, such as a front or back of the enclosure system 130. The factory interface robot 111 is calibrated using the enclosure system 130 in some implementations. The factory interface robot 111 is diagnosed using the enclosure system 130 in some implementations.

Transfer chamber 106 includes a transfer chamber robot 112. Transfer chamber robot 112 includes a robot arm with an end effector at an end of the robot arm. The end effector is configured to handle particular objects, such as wafers. In some implementations, the transfer chamber robot 112 is a SCARA robot, but may have fewer links and/or fewer degrees of freedom than the factory interface robot 111 in some implementations.

A controller 109 controls various aspects of the processing system 100. The controller 109 is and/or includes a computing device such as a personal computer, a server computer, a programmable logic controller (PLC), a microcontroller, and so on. The controller 109 includes one or more processing devices, which, in some implementations, are general-purpose processing devices such as a microprocessor, central processing unit, or the like. More particularly, in some implementations, the processing device is a complex instruction set computing (CISC) microprocessor, reduced instruction set computing (RISC) microprocessor, very long instruction word (VLIW) microprocessor, or a processor implementing other instruction sets or processors implementing a combination of instruction sets. In some implementations, the processing device is one or more special-purpose processing devices such as an application specific integrated circuit (ASIC), a field programmable gate array (FPGA), a digital signal processor (DSP), network processor, or the like. In some implementations, the controller 109 includes a data storage device (e.g., one or more disk drives and/or solid state drives), a main memory, a static memory, a network interface, and/or other components. In some implementations, the controller 109 executes instructions to perform any one or more of the methods or processes described herein. The instructions are stored on a computer readable storage medium, which include one or more of the main memory, static memory, secondary storage and/or processing device (during execution of the instructions). The controller 109 receives signals from and sends controls to factory interface robot 111 and wafer transfer chamber robot 112 in some implementations.

According to one aspect of the disclosure, to transfer content 110 (e.g., a substrate or a process kit ring) into a processing chamber 107, the content 110 is removed from a process kit enclosure system 130B via factory interface robot 111 located in FI 101. The factory interface robot 111 transfers the content 110 through one of the first vacuum ports 103a, 103b and into a respective degassing chamber 104a, 104b. A transfer chamber robot 112 located in the transfer chamber 106 removes the content 110 from one of the degassing chambers 104a, 104b through a second vacuum port 105a or 105b. The transfer chamber robot 112 moves the content 110 into the transfer chamber 106, where the content 110 is transferred to a processing chamber 107 through a respective port 108. After processing, the processed content 110 (e.g., a used process kit ring) is removed from the processing system 100 in reverse of any manner described herein.

The processing system 100 includes chambers, such as FI 101 (e.g., equipment front end module, EFEM) and adjacent chambers (e.g., load port 128, enclosure system 130, SSP, degassing chamber 104 (such as a loadlock chamber), or the like) that are adjacent to FI 101. Some or all of the chambers can be sealed. In some implementations, inert gas (e.g., one or more of nitrogen, argon, neon, helium, krypton, or xenon) is provided into one or more of the chambers (e.g., FI 101 and/or adjacent chambers) to provide one or more inert environments. In some examples, FI 101 is an inert EFEM that maintains the inert environment (e.g., inert EFEM minienvironment) within FI 101 so that users do not need to enter FI 101 (e.g., the processing system 100 is configured for no manual access within FI 101).

In some implementations, gas flow (e.g., inert gas, nitrogen) is provided into one or more chambers (e.g., FI 101) of the processing system 100. In some implementations, the gas flow is greater than leakage through the one or more chambers to maintain a positive pressure within the one or more chambers. In some implementations, the inert gas within FI 101 is recirculated. In some implementations, a portion of the inert gas is exhausted. In some implementations, the gas flow of non-recirculated gas into FI 101 is greater than the exhausted gas flow and the gas leakage to maintain a positive pressure of inert gas within FI 101. In some implementations, FI 101 is coupled to one or more valves and/or pumps to provide the gas flow into and out of FI 101. A processing device (e.g., of controller 109) controls the gas flow into and out of FI 101. In some implementations, the processing device receives sensor data from one or more sensors (e.g., oxygen sensor, moisture sensor, motion sensor, door actuation sensor, temperature sensor, pressure sensor, etc.) and determines, based on the sensor data, the flow rate of inert gas flowing into and/or out of FI 101.

The enclosure system 130 also allows for teaching, calibrating, and/or diagnosing a robot arm (e.g., of factory interface robot) without opening the sealed environment within FI 101 and adjacent chambers. The enclosure system 130 seals to the load port 128 responsive to being docked on the load port 128. The enclosure system 130 provides purge port access so that the interior of the enclosure system 130 can be purged prior to opening the enclosure system 130 to minimize disturbance of the inert environment within FI 101.

Processing system 100 can include an aligner system 150 having optical inspection functionality, as disclosed in more detail below. In one example implementation, after FI robot 111 retrieves content 110 (e.g., wafer) from one of the enclosure systems 130A-D, FI robot 111 can place content 110 on aligner system 150. Having detected arrival of content 110, aligner system 150 can cause an associated optical inspection system to collect defect inspection data. A data processing server can process the collected inspection data and make a determination whether to direct content 110 into transfer chamber 106 (for processing by one of processing chambers 107) or to return content 110 to the enclosure system 130.

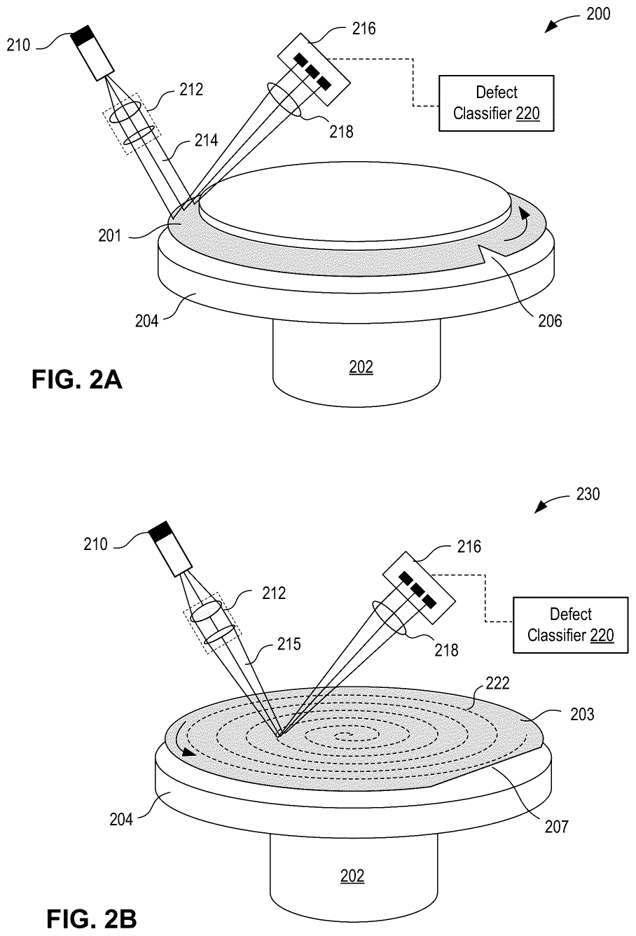

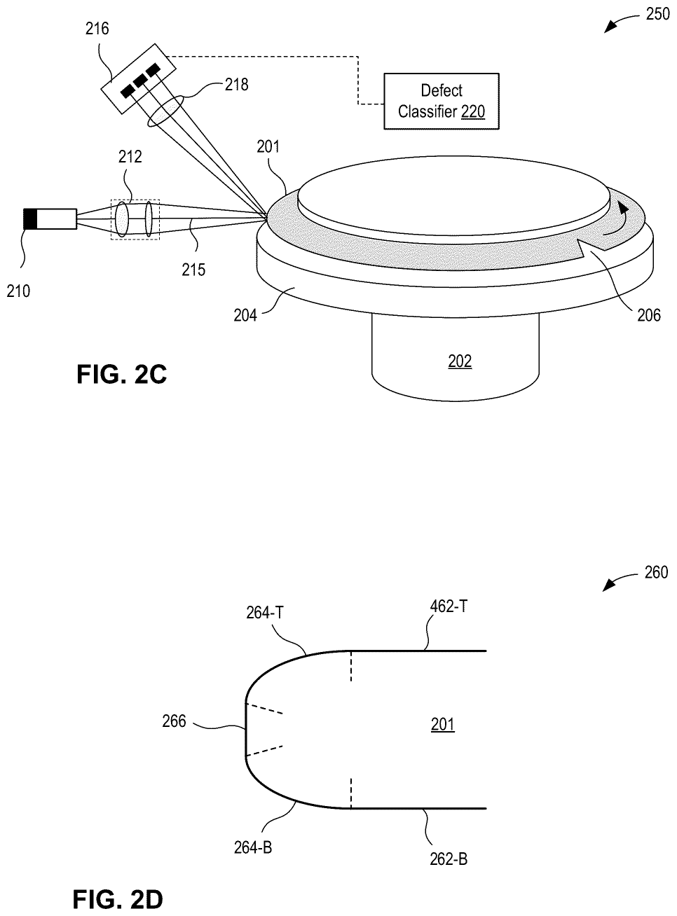

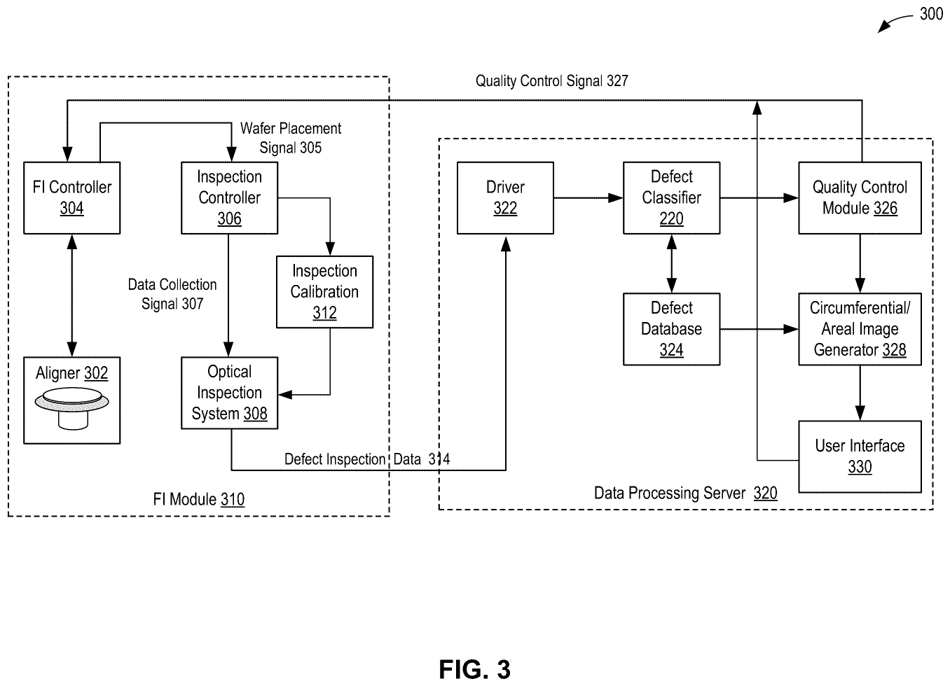

FIG. 2A illustrates a portion of an example optical inspection system 200 for detection of defects in wafers rotated by an aligner 202, in accordance with some implementations of the present disclosure. In some implementations, aligner 202 can be located within a FI of a manufacturing system (e.g., FI 101 of FIG. 1). Optical inspection system 200 can also be located within the FI. In some implementations, at least a portion of the optical inspection system 200 can be located outside the FI. For example, a light detection system of the optical inspection system 200 can collect reflected (scattered) light through a window of the FI. A wafer 201 can be supported by a rotating element 204 (e.g., chuck or clamp) of aligner 202. Rotating element 204 can rotate wafer 201 with a 50-200 rpm rotation frequency. In some implementations, rotation frequency can be below 50 rpm (e.g., 10 rpm or even lower) or above 200 rpm (e.g., 250 rpm). Aligner 202 can use rotation of wafer 201 to identify position of one or more notches 206. Notch(es) 206 can indicate specific directions of wafer 201, such as crystallographic axes of wafer 201, orientation of patterning or any other features previously deposited or etched on wafer 201, and/or the like.

Aligner 202 can use mechanical or optical techniques to locate notch(es) 206. Optical notch locators can deploy optical detectors not depicted in FIG. 2A. In some implementations, location of notches can be determined using the same optical inspection system 200 that is used for defect detection. The optical inspection system 200 can include a light source 210 configured to generate a beam of light that is used for illumination of wafer 201 or (as illustrated in FIG. 2A) an edge region of wafer 201. Light source 210 can be a pulsed laser, a continuous wave laser, a light-emitting diode, or any other suitable light source. Light source 210 can emit a narrowband light, a broadband light, a white light, and/or the like. Light emitted by light source 210 can be expanded, collimated, focused, and/or the like, by illumination optics 212, which can include any number of lenses, mirrors, beam splitters, and/or the like. In some implementations, illumination optics 212 can include masks, polarizers, and/or other optical elements to generate a polarized beam of light.

A light beam 214 generated by light source 210 and conditioned by illumination optics 212 can strike an edge of wafer 201 and reflect (and/or scatter) towards a light detector 216, passing through relay optics 218. Relay optics 218 can include one or more optical elements (e.g., lenses, mirrors, waveguides, arrays of waveguides, optical fibers, etc.) to deliver (e.g., focus) the reflected/scattered light on image sensors of light detector 216. The image sensors can include complementary metal-oxide-semiconductor (CMOS) image sensors, charge-coupled devices (CCDs), hybrid CMOS-CCD image sensors, photomultiplier tubes (e.g., an array of photocathode-based pixels), photodiodes, phototransistors, or any other suitable photon detectors. A light intensity data collected by light detector 216 can be provided to a defect classifier module 220 that determines sizes/types/concentrations/locations of various defects and imperfections in wafer 201. In some implementations, defect classifier module 220 can use one or more defect detection algorithms, such as image processing-based heuristic algorithms, machine learning techniques (e.g., decision-tree based algorithms), including deep learning neural networks (including but not limited to convolutional neural networks, fully-connected neural networks, and/or the like). In some implementations, the minimum size of defects discoverable by optical inspection system 200 can be 50 μm or even lower.

In some implementations, CMOS image sensors, CCD image sensors, and/or any other images sensing elements of light detectors 216 can operate in a time delay and integration (TDI) mode. For example, if light source 210 is a pulsed light source, each pulse can correspond to a sensing frame. In the TDI mode, each sensing pixel may aggregate electrical signals (e.g., charge signals, voltage signals, etc.) generated during multiple sensing frames. As the wafer is being rotated by aligner 202, signal aggregation in the TDI mode (synchronized with wafer 201 rotation) can be performed for pixels that capture light reflected/scattered from the same regions of rotating wafer 201 (e.g., each one or several periods of wafer 201 rotation).

FIG. 2B illustrates another example optical inspection system 230 for scanning an entire surface of wafers rotated by an aligner, in accordance with some implementations of the present disclosure. FIG. 2B illustrates an aligner device that exposes a full surface of wafer 201 to the scanning beam 215 that performs a linear scan along a spiral path 222. For illustration, FIG. 2B depicts a wafer 203 with a flat cut-out region 207 in lieu of the notch 206 in wafer 201 in FIG. 2A.

FIG. 2C illustrates a configuration 250 of the optical inspection system of FIG. 2B that is used for bevel edge scanning, in accordance with some implementations of the present disclosure. As illustrated, scanning beam 215 directed at the edge of wafer 201 with the reflected light collected by relay optics 218 and directed to light detector 216. FIG. 2D is an illustration 260 of various regions of a wafer edge that can be scanned using the configuration of FIG. 2C, in accordance with some implementations of the present disclosure. More specifically, optical inspection systems operating in accordance with implementations of the present disclosure can be used to detect defects of a top flat surface 462-A and/or a bottom flat surface 462-B of wafer 201, defects of an upper bevel region 264-T and/or a bottom bevel region 264-B, and/or defects of a bevel apex 266.

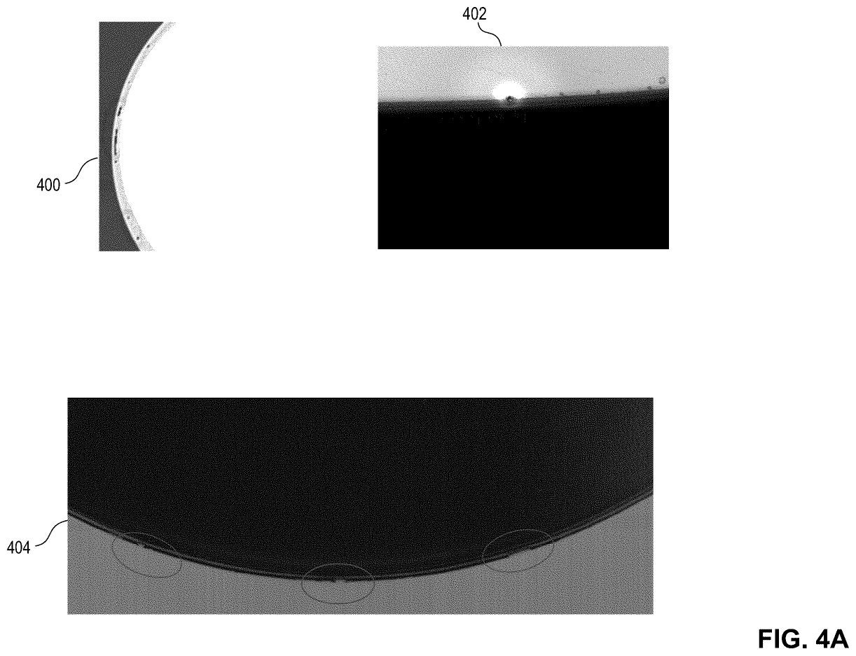

FIG. 3 illustrates an example architecture of a defect detection system 300, operating in accordance with some implementations of the present disclosure. Defect detection system 300 can include an FI module 310 and a data processing server 320. FI module 310 can include an aligner 302 (e.g., aligner 202 of FIGS. 2A-2B) configured to impart rotation to a wafer, e.g., as part of the alignment process during wafer preprocessing. Operations of aligner 302 can be controlled by FI controller 304. FI controller 304 can also control various operations of other FI tools and components, such as opening one of the load ports 128A-D, loading (using FI robot 111) a wafer (e.g., content 110) from the respective enclosure system 130 A-D, transferring the wafer from the enclosure system to FI 101, closing the load port, unsealing one of vacuum ports 103a, 103b, transferring the wafer into one of the degassing (load lock) chambers 104a, 104b, sealing the vacuum ports 103a, 103b, and or the like.

In some implementations, once the FI robot 111 has placed a wafer on aligner 302, FI controller 304 can output a wafer placement signal 305 informing an inspection controller 306 that the wafer is ready for defect inspection. Inspection controller 306 can then generate a data collection signal 307 to an optical inspection system 308 (e.g., optical inspection system 200 or optical inspection system 230 of FIG. 2). Data collection signal 307 can cause the light source and the light detector of the optical inspection system 308 to turn on and begin collection of light reflected/scattered from the wafer. Light collected by optical inspection system 308 can be digitized, denoised, authenticated, compressed, and/or otherwise preprocessed, and output—as a defect inspection data 314—to the data processing server 320.

Defect inspection data 314 can be received by a driver 322 that converts the received data into a format recognizable by a defect classifier module 220. Conversion of the received data can include decompressing the data, rescaling the data, reformatting the data, tokenizing the data, and/or the like. In some implementations, driver 322 can handle reformatting the defect inspection data into one of a plurality of formats. For example, the defect classifier module 220 can deploy different models (e.g., machine learning models) for different wafer types, with different models operating on defect inspection data 314 of different formats, images resolutions, and/or the like.

Defect classifier module 220 can identify (e.g., from a metadata provided by inspection controller 306) a type of a wafer undergoing inspection, such as a bare wafer, wafer with one or more deposited films, patterned wafer, and/or the like. Defect classifier module 220 can select a model trained to detect defects in wafers of the identified type. The selected model can process defect inspection data 314 and identify classes of defects present in the inspected area of the wafer (e.g., the edge region of the wafer, the full area of the wafer, and/or the like) and the number (or density) of such defects. Defect classifier module 220 can communicate with a defect database 324 that stores representative images of various kinds of defects. In some implementations, the stored images of defects may have been previously used to train various models of defect classifier module 220. In some implementations, images of new defects identified in the inspected wafers can be used to update the defect database 324.

The output of the defect classifier 220 can be used by a quality control module 326 to determine a suitability of the wafer for one or more processing operations. For example, a quality score can be computed for the wafer that is based on a number and classes of detected defects. Defects can include cracks, chipped areas, pits/holes, particle defects, contaminated areas, deformations, flaking/peeling, and/or any other types of imperfections and/or deviations from wafer specifications. Quality score can be computed in any suitable way, e.g., with weights being assigned to different classes of defects and to different numbers/densities of those defects. If the computed quality score is above (or at) a certain empirically determined threshold (which can be dependent on the specific wafer type), the wafer can be determined to be suitable for a subsequent downstream processing. If the computed quality score is below (or at) the empirically determined threshold, the wafer can be prevented from undergoing downstream processing. In some instances, such wafers can be directed for remedial processing (e.g., removal of deposited films, re-application of the films, edge polishing, etc.). In other instances, wafers with quality scores below a minimum acceptable threshold may be discarded. A quality control signal 327 can be communicated to the FI controller 304 directing the FI controller 304 to implement one of these actions in relation to the wafer currently being inspected.

In some implementations, a circumferential/areal image generator 328 can use the collected images of various regions of the wafer to generate one or more circumferential (e.g., for edge inspections) images or one or more areal (e.g., for line scan inspections) images of the wafer. The circumferential/areal images can be provided to a user, e.g., an operator of the processing line, via a user interface 330, which can be a computer screen or any other suitable device from which the images can be perceived by the user. In some instances, the user can review the determination made by the quality control module 326 and change the quality control signal 327 with the instructions to the FI controller 304 about further processing (or lack thereof) of the wafer.

In some implementations, FI module 310 can deploy an inspection calibration module 312 that performs periodic calibration of the optical inspection system 308. For example, inspection calibration module 312 can have access to one or more calibration wafers with known classes, numbers, and locations of defects. Calibration wafers can be used to verify and/or adjust direction, focus, polarization, pulse rate, and/or other characteristics of the illumination beam 214 (scanning beam 215), as well as positioning, focus, image acquisition rate of the light detector 216.

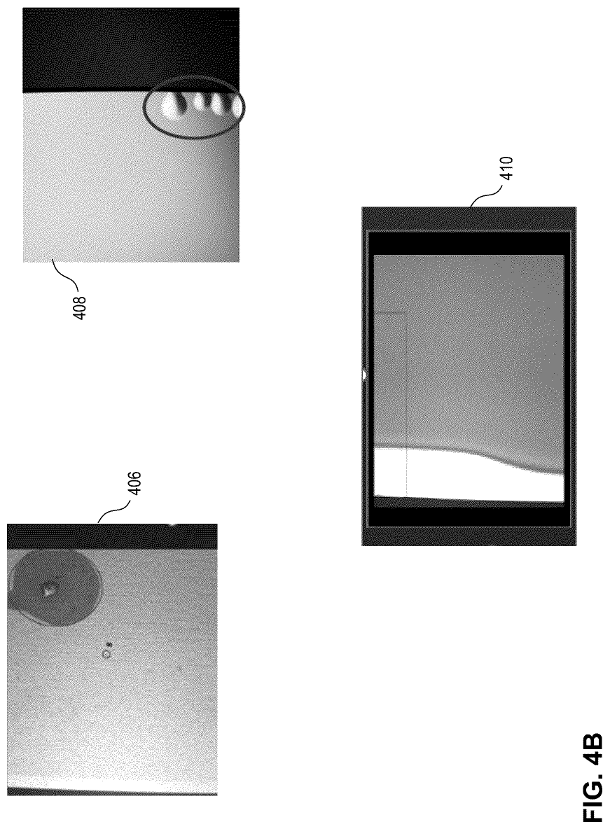

FIGS. 4A-B illustrate example edge defects that can be detected by a defect detection system illustrated in conjunction with FIG. 2 and FIG. 3, in accordance with some implementations of the present disclosure. More specifically, FIG. 4A depicts pitting defects 400, an arcing-caused edge defect 402, and edge chipping defects 404. FIG. 4B depicts stain defects 406, peeling defects 408, and bevel etch non-uniformity defect 410.

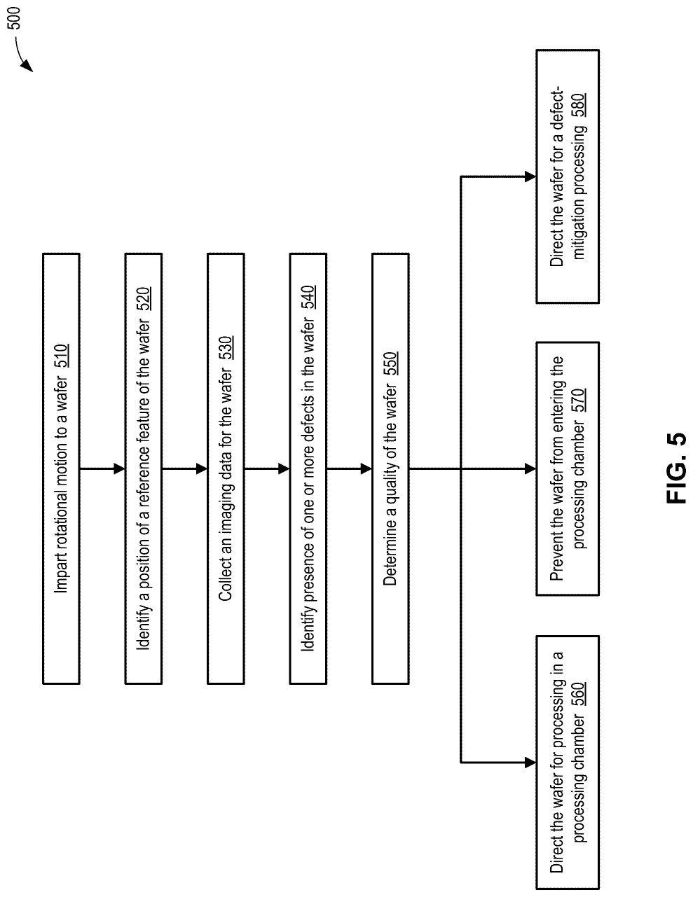

FIG. 5 is a flow diagram of an example method 500 of defect detection in wafers rotated by an aligner device, in accordance with some implementations of the present disclosure. In some implementations, method 500 is performed using systems and components shown in FIGS. 1-3 or any combination thereof. In some implementations, method 500 is performed using various processing devices, e.g., FI controller 304, inspection controller 306, and/or data processing server 320 of FIG. 3. In one implementation, the processing device(s) used to perform method 500 may deploy one or more central processing units (CPUs), microprocessors, DSPs, ASICs, finite-state machines, FPGAs, and so on, coupled to one or more memory devices (e.g., a random-access memory, a read-only memory, a flash memory, a static memory, and so on). In some implementations, the processing devices execute software or firmware instructions of method 500 stored in the memory device(s). In some implementations, some of the blocks of method 500 are optional. Method 500 can be performed on a wafer fetched (e.g., by FI robot 111 of FI 101 of FIG. 1) from a wafer carrier (e.g., one of the enclosure systems 130A-D).

At block 510, method 500 can include imparting, using an aligner device (e.g., aligner 302 of FIG. 3), a rotational motion to a wafer (e.g., as illustrated in FIG. 2). In some implementations, the rotational motion of the wafer occurs with frequency between 30 rpm and 250 rpm.

At block 520, method 500 can include identifying (e.g., using optical and electronic circuitry of the aligner device), a position of a reference feature (e.g., notch 206, flat cut-out region 207, and/or the like) of the wafer using the rotational motion of the wafer.

At block 530, method 500 can include collecting, using an optical inspection system, an imaging data for at least a portion of the wafer. The imaging data can be collected during the rotational motion imparted to the wafer. In some implementations, the aligner device and the optical inspection system are located in the FI that is coupled to at least one of a transfer chamber (e.g., transfer chamber 106), a processing chamber (e.g., processing chamber 107), or a load lock chamber (e.g., degassing chamber 104a or 104b, or some other chamber serving as an interface between the FI and the transfer chamber/processing chamber). In some implementations, collecting the imaging data by the optical inspection system is initiated (e.g., by inspection controller 306) responsive to commencement of the rotational motion of the wafer. In some implementations, the imaging data is collected for the portion of the wafer located within a distance d/10 from an edge of the wafer, d being the diameter of the wafer (e.g., 10 cm, 25 cm, 30 cm, 40 cm, and/or the like).

At block 540, method 500 can continue with identifying, using the collected imaging data, presence of one or more defects in the wafer. In some implementations, identifying presence of the one or more defects in the wafer can be performed concurrently with the aligner device identifying the position of the reference feature (e.g., within several seconds that the wafer is being rotated by the aligner). In some implementations, operations of block 540 can include deploying one or more defect detection algorithms, such as image processing-based heuristic algorithms, machine learning techniques (e.g., decision-tree based algorithms), including deep learning neural networks (including but not limited to convolutional neural networks, fully-connected neural networks, and/or the like). In some implementations, the defects identified at block 540 can include (as examples) one or more of a chipping defect, a pitting defect, a film delamination defect, a film hazing defect, a film roughness defect, a bevel-edge defect (e.g., bevel edge non-uniformity), or a staining defect.

At block 550, method 500 can include determining (evaluating), in view of the identified presence of the one or more defects in the wafer, a quality of the wafer. Depending on the determined quality, method 500 can select one of the following actions. If the quality of the wafer is at or above a threshold quality, the wafer can be determined to be suitable for further processing, and method 500 can continue (at block 560) with directing the wafer for processing in a processing chamber. If the quality of the wafer below a threshold quality, the wafer can be determined to be unsuitable for further processing, and method 500 can continue (at block 570) with preventing the wafer from entering the processing chamber. In some instances, e.g., when the wafer is not suitable for further processing but is not irreversibly impaired, method 500 can continue (at block 580) with directing the wafer for a defect-mitigation processing. Such defect-mitigation processing can include additional polishing, drying, cleaning, application of solvents, removal of improperly deposited films, and/or the like.

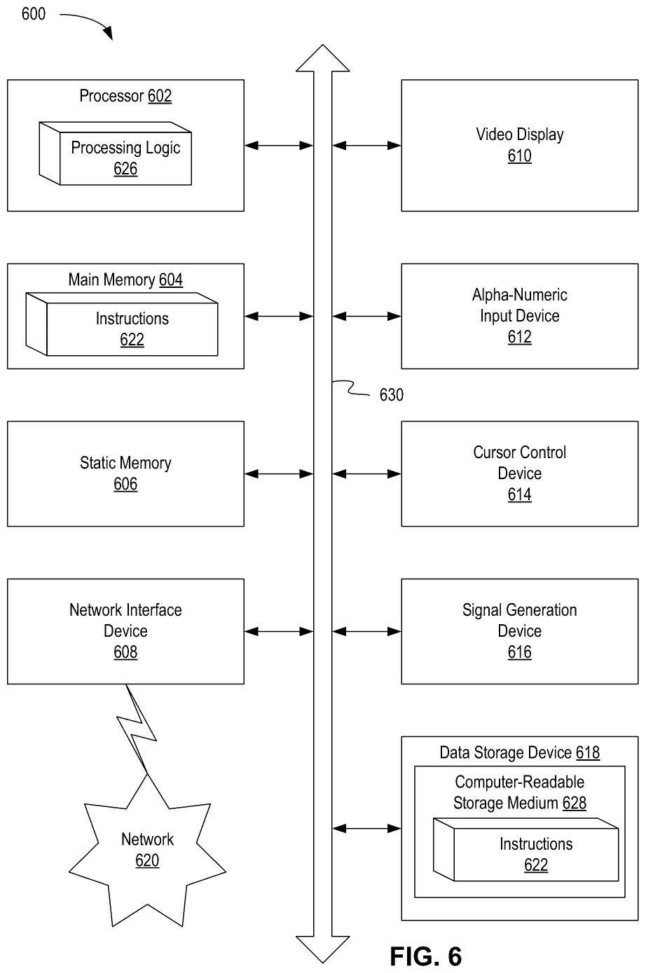

FIG. 6 depicts a block diagram of an example processing device 600 operating in accordance with some implementations of the present disclosure. The processing device 600 may be the FI controller 304, data processing server 320, or any other processing device (e.g., inspection controller 306) that performs method 500 of FIG. 5, in some implementations.

Example processing device 600 may be connected to other processing devices in a LAN, an intranet, an extranet, and/or the Internet. The processing device 600 may be a personal computer (PC), a set-top box (STB), a server, a network router, switch or bridge, or any device capable of executing a set of instructions (sequential or otherwise) that specify actions to be taken by that device. Further, while only a single example processing device is illustrated, the term “processing device” shall also be taken to include any collection of processing devices (e.g., computers) that individually or jointly execute a set (or multiple sets) of instructions to perform any one or more of the methods discussed herein.

Example processing device 600 may include a processor 602 (e.g., a CPU), which may include any suitable processing logic 626, a main memory 604 (e.g., read-only memory (ROM), flash memory, dynamic random access memory (DRAM) such as synchronous DRAM (SDRAM), etc.), a static memory 606 (e.g., flash memory, static random access memory (SRAM), etc.), and a secondary memory (e.g., a data storage device 618), which may communicate with each other via a bus 630.

Processor 602 represents one or more general-purpose processing devices such as a microprocessor, central processing unit, or the like. More particularly, processor 602 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 602 may also be one or more special-purpose processing devices such as an application specific integrated circuit (ASIC), a field programmable gate array (FPGA), a digital signal processor (DSP), network processor, or the like. In accordance with one or more aspects of the present disclosure, processor 602 may be configured to execute instructions implementing method 500 of defect detection in wafers rotated by an aligner device.

Example processing device 600 may further comprise a network interface device 608, which may be communicatively coupled to a network 620. Example processing device 600 may further comprise a video display 610 (e.g., a liquid crystal display (LCD), a touch screen, or a cathode ray tube (CRT)), an alphanumeric input device 612 (e.g., a keyboard), an input control device 614 (e.g., a cursor control device, a touch-screen control device, a mouse), and a signal generation device 616 (e.g., an acoustic speaker).

Data storage device 618 may include a computer-readable storage medium (or, more specifically, a non-transitory computer-readable storage medium) 628 on which is stored one or more sets of executable instructions 622. In accordance with one or more aspects of the present disclosure, executable instructions 622 may comprise executable instructions implementing method 500 of defect detection in wafers rotated by an aligner device.

Executable instructions 622 may also reside, completely or at least partially, within main memory 604 and/or within processor 602 during execution thereof by example processing device 600, main memory 604 and processor 602 also constituting computer-readable storage media. Executable instructions 622 may further be transmitted or received over a network via network interface device 608.

While the computer-readable storage medium 628 is shown in FIG. 6 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

It should be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

The implementations of methods, hardware, software, firmware or code set forth above may be implemented via instructions or code stored on a machine-accessible, machine readable, computer accessible, or computer readable medium which are executable by a processing element. “Memory” includes any mechanism that provides (i.e., stores and/or transmits) information in a form readable by a machine, such as a computer or electronic system. For example, “memory” includes random-access memory (RAM), such as static RAM (SRAM) or dynamic RAM (DRAM); ROM; magnetic or optical storage medium; flash memory devices; electrical storage devices; optical storage devices; acoustical storage devices, and any type of tangible machine-readable medium suitable for storing or transmitting electronic instructions or information in a form readable by a machine (e.g., a computer).

Reference throughout this specification to “one implementation” or “an implementation” means that a particular feature, structure, or characteristic described in connection with the implementation is included in at least one implementation of the disclosure. Thus, the appearances of the phrases “in one implementation” or “in an implementation” in various places throughout this specification are not necessarily all referring to the same implementation. Furthermore, the particular features, structures, or characteristics may be combined in any suitable manner in one or more implementations.

In the foregoing specification, a detailed description has been given with reference to specific exemplary implementations. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of implementation, implementation, and/or other exemplary language does not necessarily refer to the same implementation or the same example, but may refer to different and distinct implementations, as well as potentially the same implementation.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an implementation” or “one implementation” or “an implementation” or “one implementation” throughout is not intended to mean the same implementation or implementation unless described as such. Also, the terms “first,” “second,” “third,” “fourth,” etc. as used herein are meant as labels to distinguish among different elements and may not necessarily have an ordinal meaning according to their numerical designation.

What is claimed is:

1. A manufacturing system comprising:
an aligner device to:
impart a rotational motion to a wafer; and
identify, using the rotational motion of the wafer, a position of a reference feature of the wafer;
an optical inspection system to collect, during the rotational motion imparted by the aligner device to the wafer, an imaging data for at least a portion of the wafer;
a processing device to:
identify, using the collected imaging data, presence of one or more defects in the wafer.

2. The manufacturing system of claim 1, wherein the aligner device and the optical inspection system are located in a factory interface coupled to at least one of a load lock chamber, a transfer chamber, or a processing chamber.

3. The manufacturing system of claim 1, further comprising a controller coupled to the aligner and to the optical inspection system, the controller to:
initiate collection of the imaging data by the optical inspection system responsive to commencement of the rotational motion of the wafer.

4. The manufacturing system of claim 1, wherein the rotational motion of the wafer occurs with frequency between 10 rpm and 250 rpm.

5. The manufacturing system of claim 1, wherein the processing device is to identify presence of one or more defects in the wafer concurrently with the aligner device identifying the position of the reference feature.

6. The manufacturing system of claim 1, wherein the imaging data is collected for the portion of the wafer located within a distance d/10 from an edge of the wafer, wherein dis a diameter of the wafer.

7. The manufacturing system of claim 1, wherein the one or more defects comprise one or more of:
a chipping defect,
a pitting defect,
a film delamination defect,
a film hazing,
a film roughness,
a film bevel edge non-uniformity,
a bevel-edge defect, or
a staining defect.

8. The manufacturing system of claim 1, wherein the processing device is further to:
determine, in view of the identified presence of the one or more defects in the wafer, a quality of the wafer.

9. The manufacturing system of claim 8, wherein the processing device is further to:
cause, using the determined quality of the wafer, the manufacturing system to perform at least one operation comprising:
directing the wafer for processing in a processing chamber of the manufacturing system;
preventing the wafer from entering the processing chamber of the manufacturing system; or
directing the wafer for a defect-mitigation processing.

10. A system comprising:
a factory interface (FI) coupled to a wafer carrier and a load lock chamber, wherein the FI comprises:
a robot to
fetch a first wafer from the wafer carrier; and
deliver the first wafer to an aligner device;
the aligner device to:
impart a rotational motion to the first wafer; and
identify, using the rotational motion of the first wafer, a position of a reference feature of the first wafer,
an optical inspection system to collect, during the rotational motion imparted by the aligner device to the first wafer, a first imaging data for at least a portion of the first wafer; and
a processing device to:
perform a first evaluation, using the first imaging data, of a presence of one or more defects in the first wafer;
determine, using the first evaluation, that the first wafer is suitable for wafer processing; and
cause the robot to transfer the first wafer to the load lock chamber.

11. The system of claim 10, wherein the robot is further to:
fetch a second wafer from the wafer carrier; an
deliver the second wafer to the aligner device;
wherein the aligner device is further to:
impart the rotational motion to the second wafer; and
wherein the optical inspection system is further to:
collect, during the rotational motion imparted by the aligner device to the second wafer, a second imaging data for at least a portion of the second wafer; and
wherein the processing device is to:
perform a second evaluation, using the second imaging data, of a presence of one or more defects in the second wafer;
determine, using the second evaluation, that the second wafer is unsuitable for wafer processing; and
cause the robot to move the second wafer to the wafer carrier.

12. A method comprising:
imparting, using an aligner device, a rotational motion to a wafer;
identifying, using the rotational motion of the wafer, a position of a reference feature of the wafer;
collecting, using an optical inspection system, an imaging data for at least a portion of the wafer, wherein the imaging data is collected during the rotational motion imparted to the wafer; and
identifying, using the collected imaging data, presence of one or more defects in the wafer.

13. The method of claim 12, wherein the aligner device and the optical inspection system are located in a factory interface coupled to at least one of a load lock chamber, a transfer chamber, or a processing chamber.

14. The method of claim 12, wherein collecting the imaging data by the optical inspection system is initiated responsive to commencement of the rotational motion of the wafer.

15. The method of claim 12, wherein the rotational motion of the wafer occurs with frequency between 10 rpm and 250 rpm.

16. The method of claim 12, wherein identifying presence of the one or more defects in the wafer is performed concurrently with the aligner device identifying the position of the reference feature.

17. The method of claim 12, wherein the imaging data is collected for the portion of the wafer located within a distance d/10 from an edge of the wafer, wherein d is a diameter of the wafer.

18. The method of claim 12, wherein the one or more defects comprise one or more of:
a chipping defect,
a pitting defect,
a film delamination defect,
a film hazing,
a film roughness,
a film bevel edge non-uniformity,
a bevel-edge defect, or
a staining defect.

19. The method of claim 12, further comprising:
determining, in view of the identified presence of the one or more defects in the wafer, a quality of the wafer.

20. The method of claim 19, further comprising:
performing, using the determined quality of the wafer, at least one of:
directing the wafer for processing in a processing chamber;
preventing the wafer from entering the processing chamber; or
directing the wafer for a defect-mitigation processing.
